(19) United States
(12) Patent Application Publication
(10) Pub. No.: US 2025/0149292 A1
(43) Pub. Date: May 8, 2025

(54) PLASMA PROCESSING APPARATUS

(71) Applicant: Tokyo Electron Limited, Tokyo (JP)

(72) Inventor: Hiroyuki MATSUURA, Iwate (JP)

(21) Appl. No.: 18/935,538

(22) Filed: Nov. 3, 2024

(30) Foreign Application Priority Data
Nov. 7, 2023 (JP) 2023-190233

(51) Int. Cl. H01J 37/32

(52) U.S. Cl. CPC H01J 37/32091; H01J 37/3244; H01J 37/32568; H01J 37/32715; H01J 37/32834; H01J 2237/332; H01J 2237/334

(57) ABSTRACT

A plasma processing apparatus includes a processing container, a gas supply pipe that supplies a processing gas into the processing container, an exhaust unit that evacuates an inside of the processing container, a pair of electrodes arranged outside the processing container and positioned to face each other, a radio-frequency power supply that applies a radio-frequency power to the pair of the electrodes, thereby generating a capacitively-coupled plasma in the processing container, an inner tube provided in the processing container and having an opening, a substrate holder that is inserted into the inner tube and holds a plurality of substrates, a rotating shaft that supports the substrate holder, a rotation mechanism that rotates the rotating shaft, and an elevation mechanism that raises or lowers the rotating shaft. The substrate holder includes a ring member that holds a substrate, and surrounds a radial outer side of the substrate in a plan view.

### CROSS-REFERENCE TO RELATED APPLICATIONS

This application is based on and claims priority from Japanese Patent Application No. 2023-190233, filed on Nov. 7, 2023, with the Japan Patent Office, the disclosure of which is incorporated herein in its entirety by reference.

### TECHNICAL FIELD

The present disclosure relates to a plasma processing apparatus.

### BACKGROUND

Japanese Patent No. 4329403 discloses a plasma processing apparatus including a processing container, a wafer boat that holds a plurality of wafers and is inserted into and removed from the processing container, and a plasma generator provided along the height direction of the processing container, one side of the plasma generator being open to and communicating with the inside of the processing container by outwardly recessing a part of a sidewall of the processing container. Radicals generated by the plasma generator are emitted and diffused from an opening of the plasma generator toward the internal center of the processing container, flowing in a laminar state between the wafers.

### SUMMARY

According to one aspect, a plasma processing apparatus includes a processing container, a gas supply pipe that supplies a processing gas into the processing container, an exhaust unit that evacuates an inside of the processing container, a pair of electrodes arranged outside the processing container and positioned to face each other with respect to a center of the processing container, a radio-frequency power supply that applies a radio-frequency power to the pair of the electrodes, thereby generating a capacitively-coupled plasma in the processing container, an inner tube provided in the processing container and having an opening extending from one electrode to the other electrode, a substrate holder that is inserted into the inner tube and holds a plurality of substrates in a plurality of tiers, a rotating shaft that supports the substrate holder, a rotation mechanism that rotates the rotating shaft, and an elevation mechanism that raises or lowers the rotating shaft. The substrate holder includes a ring member that holds a substrate, and surrounds a radial outer side of the substrate in a plan view.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a longitudinal-sectional configuration diagram illustrating an example of a plasma processing apparatus.

FIG. 2 is a longitudinal-sectional configuration diagram viewed from the direction of arrow A, illustrating the example of the plasma processing apparatus.

FIG. 3 is a cross-sectional configuration diagram taken along line B-B, illustrating the example of the plasma processing apparatus.

FIG. 4 is an example graph illustrating a radio-frequency power applied to each electrode.

FIG. 5 is a graph illustrating an example of the plasma density in a region where a substrate is arranged between electrodes.

FIG. 6 is a graph illustrating an example of the ion current density in the substrate radial direction in a plasma processing apparatus using a wafer boat according to a reference example.

FIG. 7 is a diagram illustrating a high plasma density region in the plasma processing apparatus using the wafer boat according to the reference example.

FIGS. 8A and 8B are example diagrams illustrating a ring member and a substrate.

FIG. 9 is an example diagram illustrating an inner tube.

FIG. 10 is a longitudinal-sectional configuration diagram illustrating an example of a plasma processing apparatus with the inner tube installed in a processing container.

FIG. 11 is an example horizontal cross-sectional diagram illustrating a positional relationship between the ring member holding the substrate and the inner tube.

FIGS. 12A and 12B are example diagrams illustrating a method of adjusting the opening height.

FIG. 13 is a graph illustrating an example of the ion current density in the substrate radial direction in the plasma processing apparatuses using the wafer boat according to the reference example and the present embodiment.

FIG. 14 is a diagram illustrating a high plasma density region in the plasma processing apparatuses using the wafer boat according to the present embodiment.

### DETAILED DESCRIPTION

In the following detailed description, reference is made to the accompanying drawings, which form a part thereof. The illustrative embodiments described in the detailed description, drawings, and claims are not meant to be limiting. Other embodiments may be utilized, and other changes may be made without departing from the spirit or scope of the subject matter presented here.

Hereinafter, embodiments for carrying out the present disclosure will be described with reference to the drawings. In each drawing, the same reference numerals may be given to the same components, and redundant descriptions may be omitted.

### Plasma Processing Apparatus

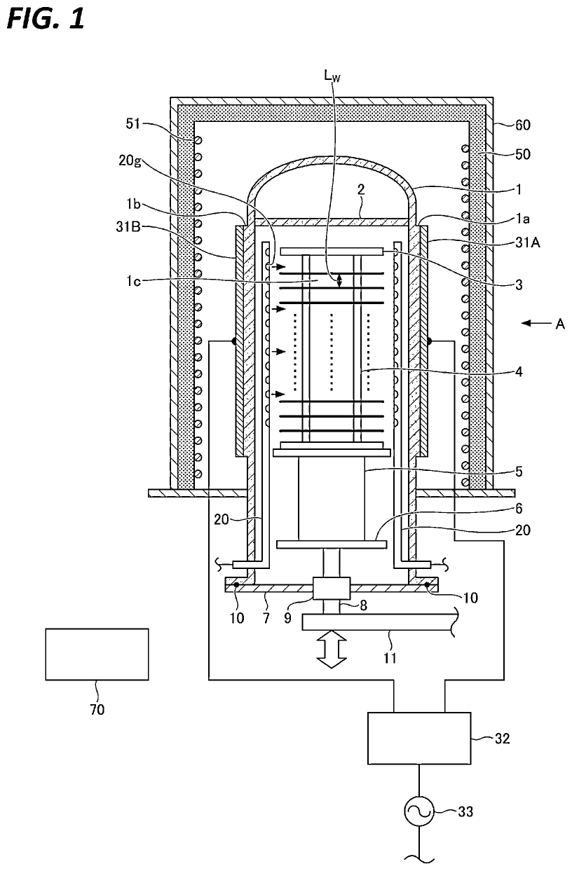

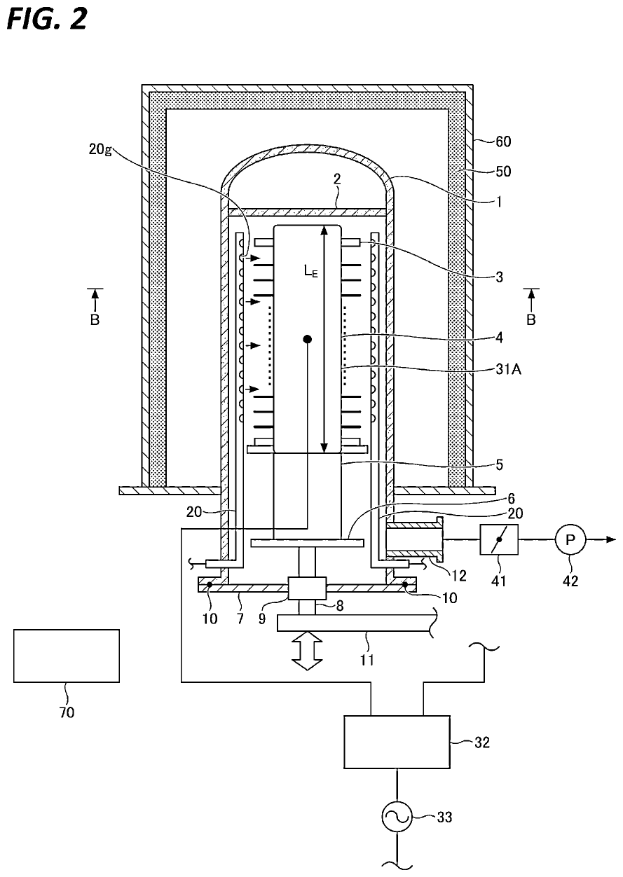

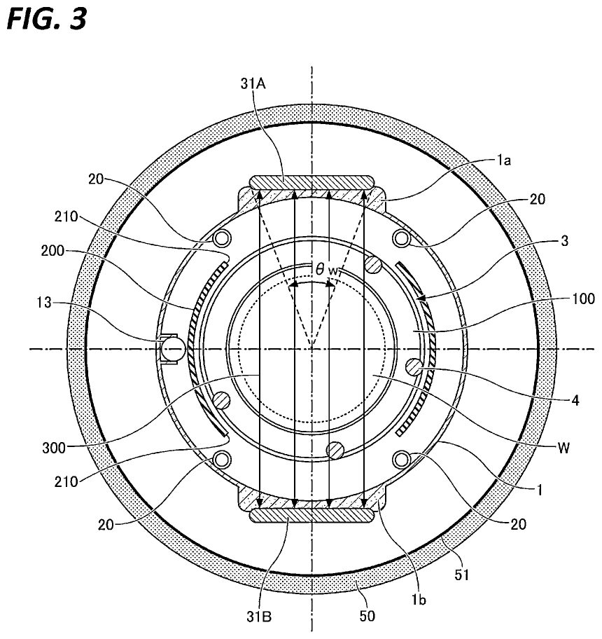

A plasma processing apparatus (e.g., a substrate processing apparatus) according to the present embodiment will be described with reference to FIGS. 1 to 3. FIG. 1 is a longitudinal-sectional configuration diagram illustrating an example of a plasma processing apparatus. FIG. 2 is a longitudinal-sectional configuration diagram viewed from the direction of arrow A illustrated in FIG. 1, illustrating the example of the plasma processing apparatus. FIG. 3 is a cross-sectional configuration diagram taken along line B-B illustrated in FIG. 2, illustrating the example of the plasma processing apparatus. The plasma processing apparatus illustrated in FIGS. 1 to 3 is a batch-type plasma processing apparatus that performs substrate processing (e.g., film formation) on a plurality of substrates W.

The plasma processing apparatus includes a ceilinged cylindrical processing container 1 with an open bottom. The entire processing container 1 is made of, for example, quartz. A ceiling plate 2, which is made of quartz, is provided near the top in the processing container 1, and a region under the ceiling plate 2 is sealed. Further, an inner tube 200 having an opening 210 (see, e.g., FIG. 3) is provided inside the processing container 1. The inner tube 200 is made of an insulator (e.g., a dielectric member) such as quartz. The opening 210 extends from one electrode 31A to the other electrode 31B. The inner tube 200 is not illustrated in FIGS. 1 and 2.

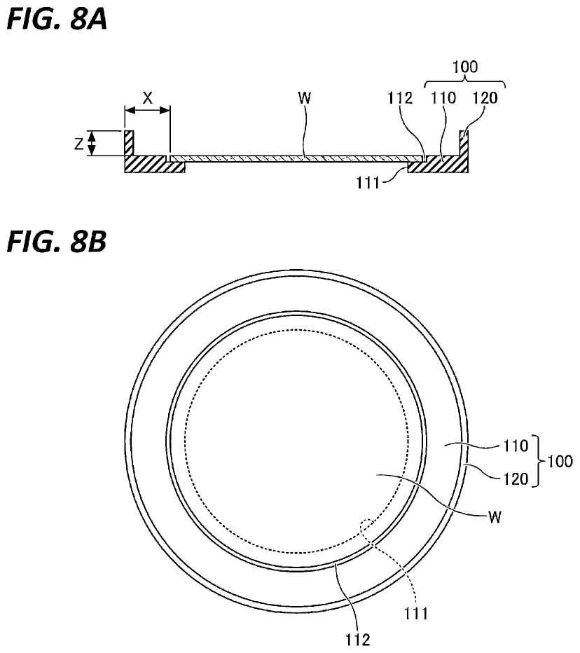

The lower sides of the processing container 1 and the inner tube 200 are open, and a wafer boat (e.g., a substrate holder) 3, in which a plurality of (e.g., several to about 100) semiconductor wafers (hereinafter referred to as “substrates W”) as processing target substrates are arranged in a plurality of tires, is inserted into the inner tube 200 from the lower sides of the processing container 1 and the inner tube 200. As such, the plurality of substrates W are approximately horizontally accommodated with a space 1c, which corresponds to an interval L_{W}, along the vertical direction inside the processing container 1. The wafer boat 3 is made of, for example, quartz. The wafer boat 3 has four rods 4 (see, e.g., FIG. 3, with two rods illustrated in FIGS. 1 and 2) and also has a plurality of ring members 100 for holding the substrates W. When the substrates W are held in the wafer boat 3, the ring members 100 surround the radial outer side of the substrates W in a plan view. The plurality of ring members 100 are arranged at predetermined intervals in the height direction and are supported by the rods 4. In FIGS. 1 and 2, the ring members 100 and the inner tube 200 are omitted. Further, details of the ring members 100 and the inner tube 200 will be described later with reference to FIGS. 8A to 14.

The wafer boat 3 is placed on a table 6 via a heat reservoir 5, which is made of quartz. The table 6 is supported on a rotating shaft 8, which penetrates a metallic (e.g., stainless steel) lid 7 that opens or closes a bottom opening of the processing container 1.

A magnetic fluid seal 9 is provided around a penetrating portion of the rotating shaft 8 to airtightly seal and rotatably support the rotating shaft 8. A sealing member 10 is provided between a peripheral portion of the lid 7 and the bottom of processing container 1 to maintain the airtightness in the processing container 1.

The rotating shaft 8 is attached to the tip of an arm 11, which is supported by an elevating mechanism (not illustrated) such as, for example, a boat elevator. The wafer boat 3 and the lid 7 are integrally moved up and down and are inserted into or removed from the processing container 1. The table 6 may be fixedly provided on the lid 7 side, such that the substrates W are processed without rotating the wafer boat 3.

Further, the plasma processing apparatus includes a wafer boat rotation mechanism (not illustrated) that rotates the wafer boat 3 inside the inner tube 200 by rotating the rotating shaft 8. Further, the plasma processing apparatus includes a wafer boat elevation mechanism (not illustrated) that raises or lowers the wafer boat 3 in the rotating shaft direction inside the inner tube 200 by axially moving the rotating shaft 8 while the lid 7 closes the bottom opening of the processing container 1.

Further, the plasma processing apparatus includes a gas supply that supplies a predetermined gas such as a processing gas or a purge gas into the processing container 1.

The gas supply includes a gas supply pipe 20. The gas supply pipe 20 is made of, for example, quartz, and inwardly penetrates the sidewall of the processing container 1 and is bent upward to extend vertically. A plurality of gas holes 20g are formed at predetermined intervals in a vertical portion of the gas supply pipe 20 over a vertical length corresponding to the wafer support range of the wafer boat 3. Each gas hole 20g ejects the gas in the horizontal direction. The processing gas is supplied to the gas supply pipe 20 from a gas source (not illustrated) through a gas pipe. The gas pipe is provided with a flow-rate controller (not illustrated) and an on-off valve (not illustrated). Thus, the processing gas from the gas source is supplied into the processing container 1 through the gas pipe and the gas supply pipe 20. The flow-rate controller is configured to be able to control the flow rate of the gas supplied from the gas supply pipe 20 into the processing container 1. The on-off valve is configured to be able to control the supply/stop of the gas supplied from the gas supply pipe 20 into the processing container 1.

FIG. 3 illustrates four gas supply pipes 20, but the number of gas supply pipes 20 is not limited thereto. Further, the four gas supply pipes 20 may be configured to supply different gases into the processing container 1, respectively. Alternatively, at least two or more gas supply pipes 20 may be configured to supply the same gas into the processing container 1.

A pair of electrodes 31A and 31B are provided outside the processing container 1. The pair of electrodes 31A and 31B are each formed of a flat plate and are installed to electrode mounts 1a and 1b provided outside the processing container 1. Further, the pair of electrodes 31A and 31B are arranged to face each other with respect to the center of the processing container 1 (e.g., the center of the substrates W supported by the wafer boat 3). In other words, the electrodes 31A and 31B are positioned 180° apart in the circumferential direction of the processing container 1. Further, the pair of electrodes 31A and 31B are arranged in parallel to each other. The electrode mounts 1a and 1b may be formed integrally with the processing container 1, or may be formed separately.

The electrodes 31A and 31B are made of a good conductor such as a metal. Further, a nickel alloy may be used as a material of the electrodes 31A and 31B. By using a nickel alloy as the material of the electrodes 31A and 31B, it is possible to minimize the impact of metal contamination to the processing container 1 (e.g., the diffusion of metal atoms to the processing container 1 made of quartz), compared to when copper is used as a material of the electrodes 31A and 31B. Further, the nickel alloy has high heat resistance, allowing it to be used within the available temperature range of the plasma processing apparatus (e.g., the temperature heated by a heating mechanism 50 to be described later; for example, within the range of room temperature to 900° C.). Further, the nickel alloy has oxidation resistance.

Each of the electrodes 31A and 31B is connected to a radio-frequency power supply 33 via an impedance matching unit 32. The radio-frequency power supply 33 and the impedance matching unit 32 constitute a radio-frequency control system. The radio-frequency control system applies an impedance-matched radio-frequency power to each of the electrodes 31A and 31B. FIGS. 1 and 2 illustrate that a radio-frequency power is supplied from a set of the impedance matching unit 32 and the radio-frequency power supply 33 to each of the electrodes 31A and 31B, but they are not limited to this configuration. In an alternative configuration, the impedance matching unit 32 and the radio-frequency power supply 33, which supply a radio-frequency power to the electrode 31A, may be separately provided from the impedance matching unit 32 and the radio-frequency power supply 33, which supply a radio-frequency power to the electrode 31B.

Power supply lines for the electrodes 31A and 31B may be connected to the electrode center. Accordingly, a radio-frequency power is applied to the center of the respective electrodes 31A and 31B.

The frequency of the radio-frequency power applied to the electrodes 31A and 31B may range from 1 kHz to 100 MHz. Further, to suppress the wavelength of voltage standing waves generated on the electrodes from affecting film formation (substrate processing), a frequency of 40 MHz or less may be used as the frequency of the radio-frequency power applied to the electrodes 31A and 31B.

The inside of the processing container 1 is evacuated and maintained at a reduced pressure (e.g., a vacuum atmosphere) by an exhaust device 42 to be described later. Further, a processing gas is supplied from the gas supply pipe 20 to the inside of the processing container 1. In contrast, the outside of the processing container 1 is in an atmospheric environment. The electrodes 31A and 31B are arranged in the atmospheric environment space outside the processing container 1.

By applying the radio-frequency power to each of the electrodes 31A and 31B from each radio-frequency power supply 33, an electric field is created in the processing container 1, and a capacitively-coupled plasma (CCP) is generated in the processing container 1.

As illustrated in FIGS. 1 and 2, the electrodes 31A and 31B are arranged in the height direction over a wider range than the height directional range of the plurality of substrates W arranged in the wafer boat 3. In other words, the width LE of the electrodes 31A and 31B in the height direction is greater than the height directional range of the plurality of substrates W arranged in the wafer boat 3. In other words, the electrodes 31A and 31B are formed up to a position higher than the uppermost substrate W arranged in the wafer boat 3, and the electrodes 31A and 31B are formed down to a position lower than the lowest substrate W arranged in the wafer boat 3.

As illustrated in FIG. 3, for the electrode 31A, an angle Ow formed by connecting both the horizontal ends of the electrode 31A with the center of the processing container 1 (e.g., the center of the substrates W supported by the wafer boat 3) is within the range of 20° to 60° in the width direction (e.g., horizontal direction). Further, the angle θW may be within the range of 25° to 40°.

Further, the width of the electrode 31B is the same as the width of the electrode 31A. Further, the pair of electrodes 31A and 31B are arranged to face each other with respect to the center of the processing container 1 (e.g., the center of the substrates W supported by the wafer boat 3) and are also arranged in parallel to each other. Thus, an electric field direction 300 created by the two electrodes 31A and 31B is indicated by arrows in FIG. 3. As illustrated in FIG. 3, a uniform electric field may be created on the substrates W.

Further, in a relationship between the heating mechanism 50 (e.g., heater wire 51) to be described later and the processing container 1, the electrodes 31A and 31B shield radiant heat from the heating mechanism 50 (e.g., heater wire 51) to the processing container 1. Therefore, the circumferential length of the processing container 1 shielded by the electrodes 31A and 31B may be, for example, equal to or less than one-third of the entire circumference. In other words, the angle θ_{W} may be equal to or less than 60°. Further, the angle θ_{W} may be within the range of 25° to 60° in consideration of the power density of the electrodes 31A and 31B and other factors.

An exhaust port 12 for the evacuation of the processing container 1 is provided on a sidewall portion of the processing container 1. An exhaust device (e.g., an exhaust port) 42, which includes a pressure control valve 41 for controlling the pressure inside the processing container 1, a vacuum pump, and others, is connected to the exhaust port 12. The inside of the processing container 1 is evacuated by the exhaust device 42 via an exhaust pipe.

Further, a thermocouple 13 is arranged along an inner wall surface of the processing container 1 inside the processing container 1. The thermocouple 13 is provided in a plural number in the height direction. A controller 70 controls temperature detection using the thermocouple 13, and the detected temperature is used to control the temperature of the substrates W.

Further, as illustrated in FIG. 3, the gas supply pipe 20 and the thermocouple 13 are arranged to avoid the electric field (e.g., the range of the electric field direction 300) generated by the electrodes 31A and 31B.

The cylindrical heating mechanism 50 is provided around the processing container 1. The heating mechanism 50 includes a wound heater wire 51. The heater wire 51 is arranged to surround the processing container 1 and the plurality of electrodes 31A and 31B. The space between the heating mechanism 50 and the processing container 1 is in the atmospheric environment, and the electrodes 31A and 31B are arranged in this space. The heating mechanism 50 heats the processing container 1 and the substrates W inside the processing container 1. The heating mechanism 50 controls the temperature of the processing container 1 to reach a desired temperature. Accordingly, the substrates W in the processing container 1 is heated by radiant heat from a wall surface of the processing container 1 and other sources. The temperature of the processing container 1 heated by the heating mechanism 50 is, for example, within the range of room temperature to 900° C. Further, in film formation, the temperature of the processing container 1 is typically, for example, within the range of 150° C. to 600° C. Further, in film formation, an appropriate temperature of the processing container 1 may be, for example, within the range of 200° C. to 500° C.

Further, a shield 60 is provided outside the heating mechanism 50. In other words, the shield 60 is arranged to surround the processing container 1, the plurality of electrodes 31A and 31B, and the heating mechanism 50. The shield 60 is made of a good conductor such as a metal, for example, and is grounded.

Further, the plasma processing apparatus includes the controller 70. The controller 70 controls, for example, the operation of each component of the plasma processing apparatus such as the supply/stop of each gas by the opening/closing of the on-off valve, the flow rate of gases by the flow-rate controller, and evacuation by the exhaust device 42. Further, the controller 70 controls, for example, the ON/OFF of the radio-frequency power by the radio-frequency power supply 33 and the temperature of the processing container 1 and the substrates W inside the processing container by the heating mechanism 50.

The controller 70 may be, for example, a computer, among others. Further, a computer program that executes the operation of each component of the plasma processing apparatus is stored in a storage medium. The storage medium may be, for example, a flexible disk, compact disk, hard disk, flash memory, DVD, or similar device. With this configuration, the plasma processing apparatus reduces the pressure inside the processing container 1 by the exhaust device 42, supplies the processing gas from the gas supply pipe 20 into the processing container 1, and applies a radio-frequency power to the electrode 31A and 31B, thereby generating a capacitively-coupled plasma (CCP) in the processing container 1 and performing a processing (e.g., film formation or etching) on the substrates W. Further, the capacitively-coupled plasma is also generated in the space 1c between the substrates W. Accordingly, the uniformity of radicals or active species generated by the plasma in central and outer peripheral portions of the substrate W may be improved. Further, it is possible to generate a sufficient concentration of radicals or active species in the central and outer peripheral portions of the substrate W to supply them to the substrate W for the substrate processing.

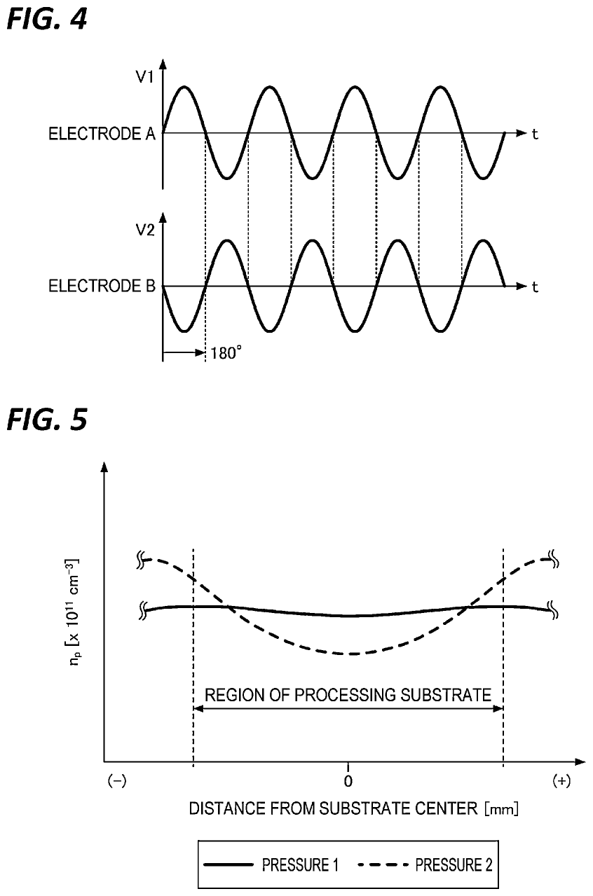

FIG. 4 is a graph illustrating an example of the radio-frequency power applied to each of the electrodes 31A and 31B. In the upper graph, the horizontal axis represents time, and the vertical axis represents the voltage applied to the electrode 31A. In the lower graph, the horizontal axis represents time, and the vertical axis represents the voltage applied to the electrode 31B.

As illustrated in FIG. 4, the radio-frequency power applied from the impedance matching unit 32 to the electrodes 31A and 31B has a voltage that is in antiphase (e.g., with a phase difference of 180°) and has the same voltage amplitude and frequency. In other words, the matching circuit of the impedance matching unit 32 is determined such that the voltage is in antiphase (e.g., with a phase difference of 180°) while maintaining the same voltage amplitude and frequency. Accordingly, a high Vpp (e.g., maximum amplitude difference of the electrode voltage) may be obtained with a low power level.

FIG. 5 is a graph illustrating an example of the plasma density nₚ in a region where the substrate is arranged between the electrodes. This example illustrates the plasma density nₚ (e.g., electron density) when a radio-frequency power of 13.56 MHz is applied to the electrodes 31A and 31B while the substrate W is not accommodated in the processing container 1, generating an argon (Ar) plasma in the processing container 1. The horizontal axis represents the distance from the center of the substrate W, with the positive direction indicating the direction toward one electrode 31A and the negative direction indicating the direction toward the other electrode 31B. The vertical axis represents the density nₚ of the generated plasma. The plasma density nₚ near the electrodes 31A and 31B is omitted.

The solid line represents the plasma density nₚ at Pressure 1. The dashed line represents the plasma density nₚ at Pressure 2, which is different from Pressure 1. There is a magnitude relationship of “Pressure 1<Pressure 2.” As illustrated in FIG. 5, by changing the pressure, it is possible to alter the plasma density distribution in the radial direction of the substrate W. In other words, controlling the pressure allows for improving the uniformity of the plasma density nₚ in the radial direction of the substrate W.

Specifically, in a hydrogen plasma, the pressure inside the processing container 1 may be set to 25 Pa or less, particularly 15 Pa or less. Accordingly, the uniformity of the plasma density in the radial direction of the substrate W may be improved.

Further, the heat reservoir 5 and the wafer boat 3 are rotated by the rotating shaft 8. Accordingly, the uniformity of the substrate processing (e.g., a plasma processing) in the circumferential direction of the substrate W may be improved.

The plurality of substrates W in the processing container 1 are held by the wafer boat 3 with a space in the height direction. Further, a capacitively-coupled plasma is generated in the processing container 1 by applying a radio-frequency power to the electrodes 31A and 31B. In other words, the plasma is generated in the space between the substrates W. Here, the interval L_{W} of the substrates W may be 10 mm or more. Accordingly, the in-plane uniformity of the plasma generated in the space between the substrates W may be improved. Further, the substrate interval may be within the range of 15 mm to 40 mm in consideration of the productivity of substrate processing by the plasma processing apparatus or the size of the processing container 1.

Further, when generating a plasma using, as the processing gas, a gas containing hydrogen (H), such as hydrogen or ammonia, synthetic quartz glass with an OH-group concentration of 200 ppm or more may be used as at least a material of the electrode mounts 1a and 1b.

Here, active species containing ions or hydrogen generated in the plasma of the gas containing hydrogen (H) cause sputtering or etching of an inner wall of the processing container 1 in the electrode mounts 1a and 1b, leading to transformation of the inner wall into a silicon-rich surface. At the boundary between the transformed inner wall portion (e.g., electrode mounts 1a and 1b) and the other unaffected inner wall portion, a significant stress may occur, potentially resulting in a damage to the processing container 1. In contrast, by using synthetic quartz glass with an OH-group concentration of 200 ppm or more for at least the electrode mounts 1a and 1b, it is possible to suppress sputtering or etching, thus suppressing transformation into a silicon-rich surface and mitigating a damage to the processing container 1.

Further, by using synthetic quartz glass with an OH-group concentration of 200 ppm or more for the inner wall of the processing container 1 in the electrode mounts 1a and 1b or for the entire processing container 1 since the inner wall of the processing container 1 is subjected to sputtering or etching by the plasma in the electrode mounts la and 1b, it is possible to relatively reduce the level of metal contamination derived from quartz compared to when using fused quartz glass made from natural natural quartz.

Here, in cases of a relatively high pressure such as “Pressure 2” illustrated in FIG. 5 or depending on the type of gas used, the plasma density increases from the vicinity of the outer periphery of the substrate toward the inner wall of the processing container 1 where the electrode mounts 1a and 1b are provided, compared to the center of the substrate W. In such cases, there is a risk that the thickness uniformity of a thin film formed on the substrate W by plasma processing may deteriorate. Further, the film quality (e.g., the microstructure, refractive index, and etching rate of the film) may also become non-uniform.

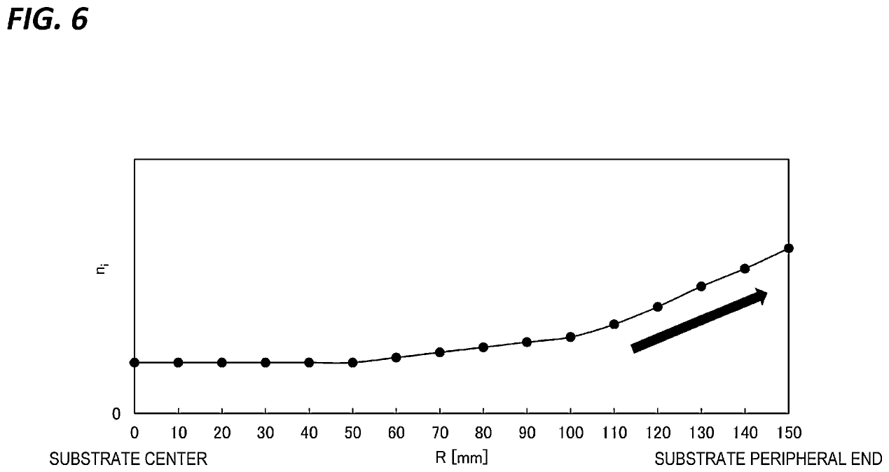

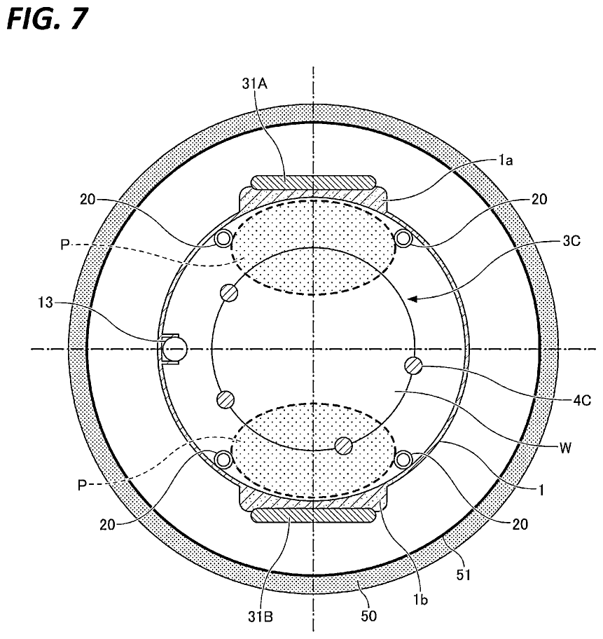

A plasma processing apparatus using a wafer boat 3C according to a reference example will be described with reference to FIGS. 6 and 7.

FIG. 6 is a graph illustrating an example of the ion current density nᵢ in the substrate radial direction in the plasma processing apparatus using the wafer boat 3C according to a reference example. In FIG. 6, the horizontal axis represents the distance R (mm) in the direction from the center of the substrate W toward the electrode mount 1a (or the electrode mount 1b). In this example, the radius of the substrate W is set to 150 (mm). The vertical axis represents the ion current density nᵢ incident from the plasma onto the substrate W. FIG. 7 is a diagram illustrating a high plasma density region P in the plasma processing apparatus using the wafer boat 3C according to the reference example.

In the plasma processing apparatus according to the reference example, the inner tube 200 (see, e.g., FIG. 3) is not provided in the processing container 1, and the wafer boat 3C is inserted into the processing container 1. The wafer boat 3C according to the reference example is provided with a plurality of rods 4C as illustrated in FIG. 7 (e.g., four rods in the example of FIG. 7), and the outer peripheral portion of the substrate W is inserted into grooves (not illustrated) provided in the rods 4C, so that the grooves (not illustrated) of the rods 4C hold the substrate W. In other words, there is a space between the outer peripheral end of the substrate W and the inner wall of the processing container 1.

In the wafer boat 3C according to the reference example, an example of the measurement results of the ion current density nᵢ incident from the plasma onto the substrate W is illustrated in the graph of FIG. 6. The ion current density nᵢ gradually increases with decreasing distance from the substrate center toward the substrate outer peripheral end (see, e.g., the black arrow).

In FIG. 7, the high plasma density region P is indicated by a dashed line. The high plasma density region P is formed in a region from the vicinity of the outer peripheral end of the substrate to inner walls of the electrode mounts 1a and 1b. The high plasma density region P has a higher ion current density nᵢ incident onto the substrate. This high plasma density region P (where the ion current density nᵢ increases) overlaps with the outer periphery of the substrate W.

Next, the plasma processing apparatus according to the present embodiment will be described with reference to FIGS. 8A to 14.

FIGS. 8A and 8B are example diagrams illustrating the ring member 100 and substrate W. FIG. 8A is an example longitudinal-sectional view of the ring member 100 and the substrate W held by the ring member 100. FIG. 8B is an example plan view of the ring member 100 and the substrate W held by the ring member 100.

Here, the wafer boat 3 of the plasma processing apparatus according to the present embodiment includes a plurality of rods 4 (e.g., four rods in the example of FIGS. 8A and 8B) and a plurality of ring members 100.

The ring member 100 is a flat plate member with a circular outer periphery in a plan view, and has an annular shape portion 110 with a circular opening 111 that is formed from the upper surface to the lower surface through the center of the circular flat plate member. Further, the annular shape portion 110 has a circular recess 112 formed in the upper surface in a plan view for holding (e.g., accommodating) the substrate W. The radius of the recess 112 is slightly larger than the radius of the substrate W. The recess 112 is in communication with the opening 111. Further, the circular flat plate member, the circular opening 111, the circular recess 112, and a vertical wall portion 120 to be described later are formed concentrically in a plan view. Further, the depth of the recess 112 is approximately the same as the thickness of the substrate W, for example. Accordingly, the upper surface of the substrate W may align with the upper surface of the annular shape portion 110 when the substrate W is placed in the recess 112.

Further, the ring member 100 has the vertical wall portion 120 that stands on the upper surface of the annular shape portion 110. The vertical wall portion 120 is formed in a cylindrical shape. The annular shape portion 110 and the vertical wall portion 120 are formed such that the radii of the outer peripheral surfaces thereof are the same and the outer peripheral surfaces are aligned with each other (see, e.g., FIG. 8A). They are not limited to this configuration, and the radius of the outer peripheral surface of the vertical wall portion 120 may be smaller than the radius of the outer peripheral surface of the annular shape portion 110.

Further, the radius of the inner peripheral surface of the vertical wall portion 120 is larger than the radius of the inner peripheral surface of the ring member 100 (the inner peripheral surface of the opening 111). Further, the radius of the inner peripheral surface of the vertical wall portion 120 is larger than the radius of the circumferential surface of the recess 112.

Further, the ring member 100 [including the annular shape portion 110 and the vertical wall portion 120] is made of an insulating member (e.g., a dielectric member). Specifically, the ring member 100 (e.g., including the annular shape portion 110 and the vertical wall portion 120) may be made of quartz. Further, the annular shape portion 110 and the vertical wall portion 120 of the ring member 100 may be integrally formed. Further, the annular shape portion 110 and the vertical wall portion 120 may be formed separately and assembled to form the ring member 100. Further, the ring member 100 is electrically floating.

Further, the plurality of ring members 100 of the wafer boat 3 are arranged in the height direction at predetermined intervals. One substrate W is held by one ring member 100. The plurality of ring members 100 are connected to each other by the plurality of rods 4 extending in the height direction. Further, the plurality of ring members 100 are arranged concentrically.

The distance X from the outer peripheral end of the substrate W to the outer peripheral end of the ring member 100 may be 10 mm or more and 80 mm or less, and particularly, may be 20 mm or more and 50 mm or less.

The height Z of the vertical wall portion 120 may be 0 mm or more and 10 mm or less. Further, the height Z of the vertical wall portion 120 is less than the interval L_{W} of the substrates W (see, e.g., FIG. 1). This creates a gap for transferring the substrate W between the upper surface of the vertical wall portion 120 of one ring member 100 and the lower surface of the annular shape portion 110 of another adjacent ring member 100 located above the one ring member 100.

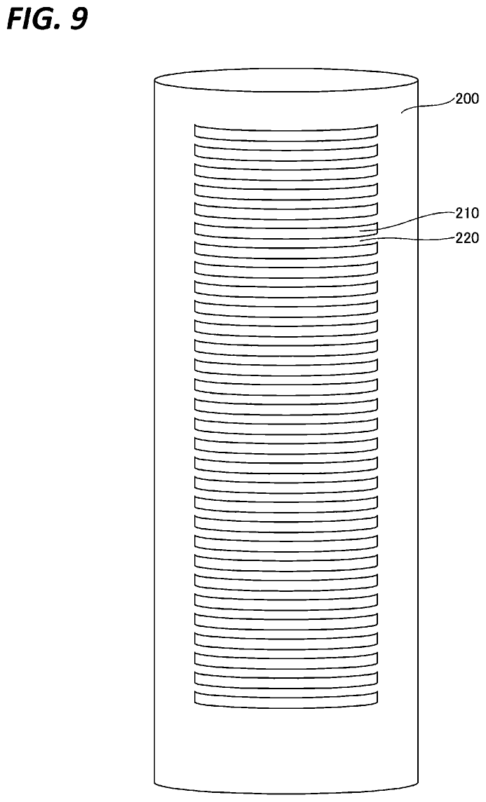

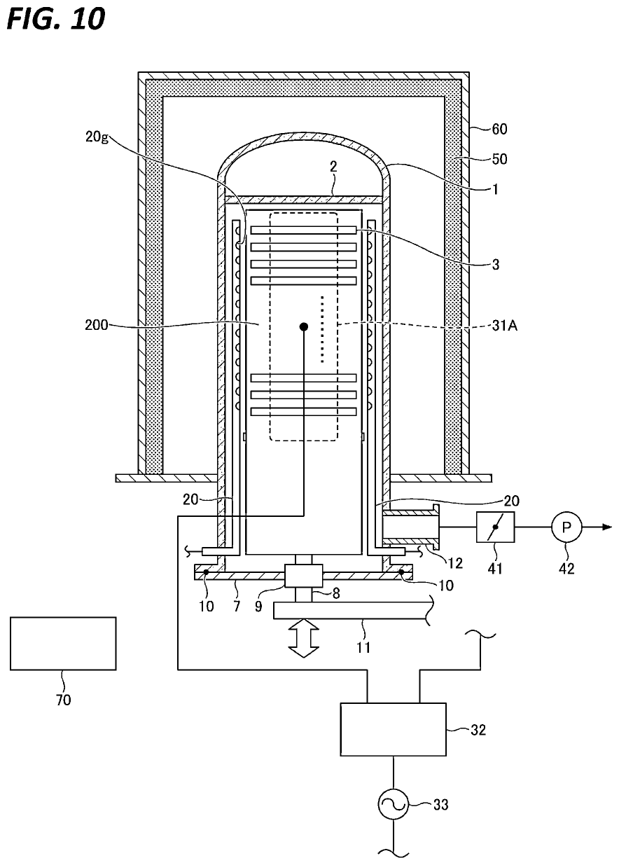

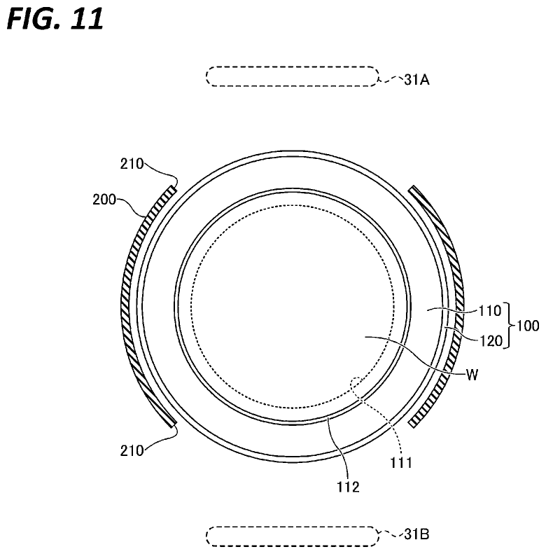

FIG. 9 is an example diagram illustrating the inner tube 200. FIG. 10 is a longitudinal-sectional configuration diagram illustrating an example of the plasma processing apparatus with the inner tube 200 installed in the processing container 1. FIG. 11 is an example horizontal cross-sectional diagram illustrating a positional relationship between the ring member 100 holding the substrate W and the inner tube 200.

The inner tube 200 has a cylindrical shape and is open at the bottom. The wafer boat 3 may be inserted through a bottom opening of the inner tube 200. The top of the inner tube 200 may be open, or may be closed. The inner tube 200 is made of an insulating member (e.g., a dielectric member). Specifically, the inner tube 200 may be made of quartz.

The inner tube 200 has a horizontally elongated opening 210 in the direction where the electrodes 31A and 31B are provided. A plurality of openings 210 are provided in the height direction (e.g., the axial direction of the inner tube 200). Further, ribs 220 are provided between the respective openings 210 adjacent to each other in the height direction. In other words, the openings 210 and the ribs 220 are alternately provided on a sidewall of the inner tube 200 in the height direction. Here, the number of ribs 220 may be equal to the number of ring members 100 provided in the wafer boat 3. Further, the pitch at which the ribs 220 are provided on the inner tube 200 (e.g., the center-to-center distance between the adjacent ribs 220 in the height direction) is equal to the pitch at which the ring members 100 are provided in the wafer boat 3 (the center-to-center distance between the adjacent ring members 100 in the height direction).

As illustrated in FIG. 11, the opening 210 is provided in the direction from the center of the rotating shaft 8 toward one electrode 31A and the opening 210 is provided in the direction from the center of the rotating shaft 8 toward the other electrode 31B. When viewed in the direction from one electrode 31A to the other electrode 31B, the width of the openings 210 may be greater than the width of the electrodes 31A and 31B.

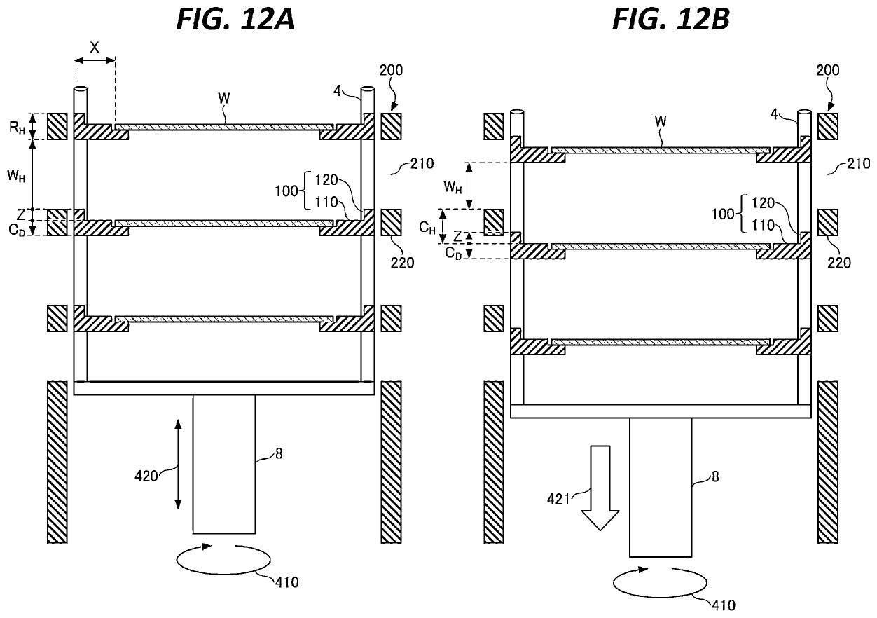

Next, a method of adjusting the opening height will be described with reference to FIGS. 12A and 12B. FIGS. 12A and 12B are example diagrams illustrating a method of adjusting the opening height.

The wafer boat 3 is connected to the rotating shaft 8. The rotating shaft 8 is rotated in a rotational direction 410 by the wafer boat rotation mechanism (not illustrated). By rotating the rotating shaft 8, the wafer boat 3 rotates inside the inner tube 200. Further, the rotating shaft 8 is moved in an axial direction (e.g., a vertical direction) 420 by the wafer boat elevation mechanism (not illustrated). The wafer boat elevation mechanism raises or lowers the rotating shaft 8, for example, with a resolution of 0.2 mm. By raising or lowering the rotating shaft 8, the wafer boat 3 is raised or lowered inside the inner tube 200.

FIG. 12A illustrates a state where the wafer boat 3 is positioned at the reference position (home position) of the wafer boat 3. The reference position (e.g., a home position) of the wafer boat 3 is the position where the upper surface position of the rib 220 is aligned with the upper surface position of the vertical wall portion 120 in the height direction.

Here, the thickness of the annular shape portion 110 is denoted as C_{D}. The height of the vertical wall portion 120 is denoted as Z. The height of the rib 220 is denoted as R_{H}. The opening height as seen from the outside of the inner tube 200 is denoted as W_{H}. As illustrated in FIG. 12A, the height R_{H} of the rib 220 may be the same as the height (C_{D}+Z) of the ring member 100. Further, at the reference position (home position) of the wafer boat 3, the height R_{H} of the rib 220 may be up to 4 mm longer than the height (C_{D}+Z) of the ring member 100, allowing the rib 220 to protrude downward. That is, it may be expressed as R_{H}=C_{D}+Z+α (where 0 (mm)≤α≤4 (mm).

Further, the clearance between an inner wall of the inner tube 200 and the wafer boat 3 may be about 5 mm.

In a state illustrated in FIG. 12A, the opening height W_{H}, as seen from the outside of the inner tube 200, is the height from the upper surface position of the rib 220 (e.g., the upper surface position of the vertical wall portion 120) to the lower surface position of the rib 220, which is adjacent in the height direction via the opening 210 therebetween.

FIG. 12B illustrates a state where the wafer boat 3 is moved in a downward direction 421 from the reference position (e.g., a home position) of the wafer boat 3. In this state, the upper surface position of the vertical wall portion 120 is lower than the upper surface position of the rib 220 and is higher than the lower surface position of the rib 220. Further, the lower surface position of the ring member 100 is lower than the lower surface position of the rib 220.

In the state illustrated in FIG. 12B, the opening height W_{H}, as seen from the outside of the inner tube 200, is the height from the upper surface position of the rib 220 to the lower surface position of the ring member 100. As such, the opening height W_{H} may be reduced by lowering the wafer boat 3 using the wafer boat elevation mechanism (not illustrated). Further, the apparent height of the vertical wall portion 120 as viewed from the electrodes 31A and 31B may be denoted as C_{H} (where C_{H}>Z). The apparent height C_{H} of the vertical wall portion 120 ensures that the lower surface of the rib 220 does not exceed the upper surface of the vertical wall portion 120 and is specifically defined as C_{H}<Z+R_{H}.

Here, the rib 220 of the inner tube 200 and the vertical wall portion 120 of the ring member 100 are electrically floating, and an ion sheath is generated on their surfaces by a plasma. Then, the rib 220 and the vertical wall portion 120 with the ion sheath generated thereon shield the electric field generated between the electrodes 31A and 31B.

The controller 70 controls the wafer boat elevation mechanism to move the wafer boat 3 to the reference position (see, e.g., FIG. 12A). Then, the wafer boat 3 is moved down until the plasma density on the substrate W reaches a desired uniformity (see, e.g., FIG. 12B). This adjusts the opening height W_{H} as viewed from the electrodes 31A and 31B, and adjusts the plasma density on the substrate W, thereby adjusting the ion current density nᵢ incident from the plasma onto the substrate W.

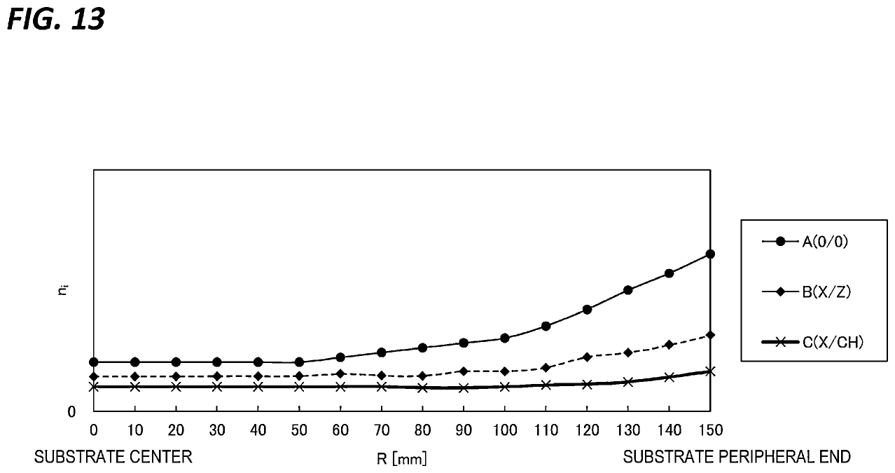

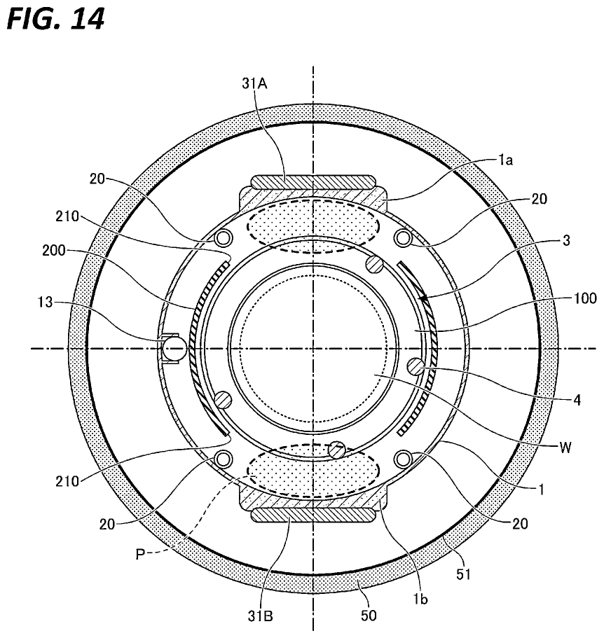

FIG. 13 is a graph illustrating an example of the ion current density in the substrate radial direction in the plasma processing apparatus using the wafer boat 3 according to the reference example and the present embodiments. In FIG. 13, the horizontal axis represents the distance R (mm) in the direction from the center of the substrate W toward the electrode mount 1a (or the electrode mount 1b). In this example, the radius of the substrate W is set to 150 (mm). The vertical axis represents the ion current density nᵢ incident from the plasma onto the substrate W. FIG. 14 is a graph illustrating the high plasma density region P in the plasma processing apparatus using the wafer boat 3 according to the present embodiments.

Here, in FIG. 13, the symbol “A” represents the ion current density results for the wafer boat 3C according to the reference example (e.g., distance X=0 (mm) and apparent height of the vertical wall portion 120=0 (mm)). The symbol “B” represents the ion current density results for the wafer boat 3 according to the present embodiment, which is at the reference position (e.g., distance X=X1 (mm) and apparent height of the vertical wall portion 120=Z (mm)). The symbol “C” represents the ion current density results for the wafer boat 3 according to the present embodiment, which is at the lowered position (e.g., distance X=X1 (mm) and height Z=C_{H} (mm)).

As illustrated by the comparison between “A” and “B”, a decrease in ion current density nᵢ near the substrate outer periphery may be increased by providing the ring member 100 and the inner tube 200.

As illustrated by the comparison between “B” and “C”, by adjusting the apparent height of the vertical wall portion 120, the uniformity of the plasma density may be controlled and the uniformity of the ion current density nᵢ may be controlled.

As described above, the provision of the ring member 100 and the inner tube 200 has the effect of reducing the ion current density (e.g., a plasma density) near the substrate outer periphery and improving the substrate in-plane distribution uniformity of the plasma density. Further, the substrate in-plane distribution uniformity of the plasma density may be improved by raising or lowering the wafer boat 3.

In FIG. 14, the high plasma density region P in the wafer boat 3 is indicated by a dashed line. Compared to cases without the ring member 100 and the inner tube 200 (see, e.g., FIG. 7), the high plasma density region P decreases toward the electrodes 31A and 31B in cases with the ring member 100 and the inner tube 200 (see, e.g., FIG. 14). Further, the region where the high plasma density region P overlaps with the substrate W also decreases.

Further, by using the ring member 100 with the vertical wall portion 120, the diameter of the ring member 100 may be reduced. Thus, the diameter of the processing container 1 may also be reduced, allowing for the miniaturization of the plasma processing apparatus.

According to one aspect, it is possible to provide a plasma processing apparatus that generates a plasma on a substrate to process the substrate.

From the foregoing content, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising:
a processing container;
a gas supply pipe configured to supply a processing gas into the processing container;
an exhaust port configured to evacuate an inside of the processing container;
a pair of electrodes arranged outside the processing container and positioned to face each other with respect to a center of the processing container;
a radio-frequency power supply configured to apply a radio-frequency power to the pair of the electrodes, thereby generating a capacitively-coupled plasma in the processing container;
an inner tube provided in the processing container and having an opening extending from one electrode to a remaining electrode;
a substrate holder inserted into the inner tube and configured to hold a plurality of substrates in a plurality of tiers;
a rotating shaft configured to support the substrate holder;
a rotating source configured to rotate the rotating shaft; and
a lift configured to raise or lower the rotating shaft,
wherein the substrate holder includes a ring plate configured to hold a substrate, and surrounds a radial outer side of the substrate in a plan view.

2. The plasma processing apparatus according to claim 1, wherein the ring plate includes:
an annular-shaped portion configured to hold the substrate; and
a vertical wall portion provided on an upper surface of the annular-shaped portion.

3. The plasma processing apparatus according to claim 2, wherein the inner tube and the ring plate are each made of an insulating material.

4. The plasma processing apparatus according to claim 1, wherein the opening has a greater width than that of the electrodes when viewed in a direction from the one electrode to the remaining electrode.

5. The plasma processing apparatus according to claim 1, wherein a plurality of openings and a plurality of ring plates are arranged in a height direction.

6. The plasma processing apparatus according to claim 5, wherein the plurality of openings and a plurality of ribs between the openings adjacent in the height direction are alternately provided on the inner tube, and
a pitch that the plurality of ribs are provided is equal to a pitch that the plurality of ring plates are provided.

7. The plasma processing apparatus according to claim 6, wherein each of the plurality of ribs has a height equal to or greater than that of each of the plurality of ring plates.

8. The plasma processing apparatus according to claim 1, further comprising a controller,
wherein the controller controls the lift to control a density of the plasma formed on a surface of the substrate.
